(19) United States
(12) Patent Application Publication
(10) Pub. No.: US 2026/0059664 A1
(43) Pub. Date: Feb. 26, 2026

(54) ELECTRONIC DEVICE AND MANUFACTURING METHOD THEREOF

(71) Applicant: Innolux Corporation, Miaoli County (TW)

(72) Inventor: Po-Yun Hsu, Miaoli County (TW)

(73) Assignee: Innolux Corporation, Miaoli County (TW)

(21) Appl. No.: 19/280,157

(22) Filed: Jul. 25, 2025

Related U.S. Application Data
(60) Provisional application No. 63/685,272, filed on Aug. 21, 2024.

(30) Foreign Application Priority Data
Mar. 26, 2025 (CN) 202510367504.5

(51) Int. Cl. H05K 1/11; H05K 1/02; H05K 1/18; H05K 3/00; H05K 3/46

(52) U.S. Cl. CPC H05K 1/116; H05K 1/0266; H05K 1/181; H05K 3/0067; H05K 3/007; H05K 3/4617; H05K 3/4638; H05K 2201/09481; H05K 2203/063; H05K 2203/166

(57) ABSTRACT

A manufacturing method of an electronic device including the following steps is provided. A carrier is provided, wherein the carrier has a base layer and a temporary adhesive layer disposed on the base layer. A first sub-perforation substrate disposed on a platform is provided. A first laminating step is performed to laminate the base layer to the first sub-perforation substrate through the temporary adhesive layer to form a substrate structure. A second sub-perforation substrate is provided, and the second sub-perforation substrate is laminated to the first sub-perforation substrate. When performing the first laminating step, position along a normal direction of the platform, the carrier moves from a first position to a second position, and a distance between the first position and the platform is greater than a distance between the second position and the platform. The electronic device is also provided.

### CROSS-REFERENCE TO RELATED APPLICATION

This application claims the priority benefit of U.S. provisional application Ser. No. 63/685,272, filed on Aug. 21, 2024, and China application serial no. 202510367504.5, filed on Mar. 26, 2025. The entirety of each of the above-mentioned patent applications is hereby incorporated by reference herein and made a part of this specification.

### BACKGROUND

### Technical Field

The disclosure relates to an electronic device and a manufacturing method thereof, and more particularly to a package structure and a manufacturing method thereof.

### Description of Related Art

An electronic device formed using a 2.5D package process (for example, CoWoS package technology) or a 3D package process usually includes a substrate having a perforation, which may provide a relatively short signal transmission path, so that the electronic device may have an improved performance. The substrate having the perforation may be formed by first performing a perforation process on each of two relatively thin sub-substrates and then performing a laminating process. However, the sub-substrates may be damaged during the perforation process and/or the laminating process due to insufficient rigidity, which may reduce the yield of the electronic device including the sub-substrates.

### SUMMARY

The disclosure provides a manufacturing method of an electronic device, and the manufactured electronic device may have an improved yield.

According to some embodiments of the disclosure, a manufacturing method of an electronic device is provided and includes the following steps. A carrier is provided. The carrier has a base layer and a temporary adhesive layer disposed on the base layer. A first sub-perforation substrate disposed on a platform is provided. The first laminating step is performed to laminate the base layer to the first sub-perforation substrate through the temporary adhesive layer to form a substrate structure. A second sub-perforation substrate is provided, and the second sub-perforation substrate is laminated to the first sub-perforation substrate. When performing the first fitting step, along a normal direction of the platform, the carrier moves from a first position to a second position, and a distance between the first position and the platform is greater than a distance between the second position and the platform.

The disclosure provides an electronic device, which may have an improved yield.

According to some embodiments of the disclosure, the electronic device is provided, which includes a first sub-perforation substrate and a second sub-perforation substrate. The first sub-perforation substrate includes a plurality of first perforations. The second sub-perforation substrate is laminated to the first sub-perforation substrate and includes a plurality of second perforations. The first perforations at least partially overlap with the corresponding second perforations in a normal direction of the first sub-perforation substrate. A misalignment between the second sub-perforation substrate and the first sub-perforation substrate in the first direction is less than or equal to 5 μm, and the first direction is perpendicular to the normal direction of the first sub-perforation substrate. A thickness of one of the first perforations and one of the second perforations in the normal direction of the first sub-perforation substrate is less than or equal to 0.3 mm. A maximum width of one of the first perforations and one of the second perforations in the first direction is less than or equal to 100 μm. An angle between a side of the first sub-perforation substrate and the normal direction of the first sub-perforation substrate is less than or equal to 10 degrees, and an angle between a side of the second sub-perforation substrate and the normal direction of the first sub-perforation substrate is less than or equal to 10 degrees.

In order for the features and advantages of the disclosure to be more comprehensible, the following specific embodiments are described in detail in conjunction with the drawings.

### BRIEF DESCRIPTION OF THE DRAWINGS

FIG. 1 is a flow schematic diagram of a manufacturing method of a perforation substrate according to an embodiment of the disclosure.

FIG. 2 is a cross-sectional schematic diagram of a perforation substrate according to a first embodiment of the disclosure.

FIG. 3 is a cross-sectional schematic diagram of a perforation substrate according to a second embodiment of the disclosure.

FIG. 4 is a cross-sectional schematic diagram of a perforation substrate according to a third embodiment of the disclosure.

FIG. 5 is a flow schematic diagram of a manufacturing method of a perforation substrate according to a fourth embodiment of the disclosure.

FIG. 6 is a flow schematic diagram of a manufacturing method of a perforation substrate according to a fifth embodiment of the disclosure.

FIG. 7 is a flow schematic diagram of a manufacturing method of an electronic device according to the first embodiment of the disclosure.

FIG. 8 is a partial cross-sectional schematic diagram of an electronic device according to the second embodiment of the disclosure.

FIG. 9 is a partial cross-sectional schematic diagram of an electronic device according to the third embodiment of the disclosure.

FIG. 10 is a partial cross-sectional schematic diagram of an electronic device according to the fourth embodiment of the disclosure.

### DESCRIPTION OF THE EMBODIMENTS

Reference will now be made in detail to the exemplary embodiments of the disclosure, examples of the exemplary embodiments are illustrated in the drawings. Wherever possible, the same reference numerals are used in the drawings and the description to refer to the same or similar parts.

The disclosure may be understood by referring to the following detailed description in conjunction with the drawings. It should be noted that in order to facilitate the understanding of the reader and the brevity of the drawings, multiple drawings in the disclosure only depict a part of an electronic device, and specific elements in the drawings are not drawn according to actual scale. In addition, the number and the size of each element in the drawings are for illustration only and are not intended to limit the scope of the disclosure.

Throughout the specification and the appended claims of the disclosure, certain terms may be used to refer to specific elements. It should be understood by persons skilled in the art that electronic device manufacturers may refer to the same element by different names. The disclosure does not intend to distinguish between elements with the same function but different names. In the following specification and claims, terms such as “including”, “containing”, and “having” are open-ended terms, so the terms should be interpreted as “containing but not limited to . . .”. Therefore, when the terms “including” , “containing”, and/or “having” are used in the description of the disclosure, the terms designate the presence of a corresponding feature, region, step, operation, and/or component, but do not exclude the presence of one or more corresponding features, regions, steps, operations, and/or components.

Directional terms such as “upper”, “lower”, “front”, “rear”, “left”, and “right” mentioned in the disclosure are only directions with reference to the drawings. Therefore, the used directional terms are used to illustrate, but not to limit, the disclosure. In the drawings, each drawing illustrates the general features of a method, a structure, and/or a material used in a specific embodiment. However, the drawings should not be construed to define or limit the scope or the nature covered by the embodiments. For example, for clarity, relative sizes, thicknesses, and positions of various film layers, regions, and/or structures may be reduced or enlarged.

When a corresponding component (for example, a film layer or a region) is referred to as being “on another component”, the component may be directly on the other component or there may be another component between the two. On the other hand, when a component is referred to as being “directly on another component”, there is no component between the two. In addition, when a component is referred to as being “on another component”, the two have an upper-lower relationship in the top view direction, and the component may be above or below the other component, and the upper-lower relationship depends on the orientation of the device.

The terms “equal” or “same”, “substantially”, or “roughly” are generally interpreted as within 20% of a given value or range or interpreted as within 10%, 5%, 3%, 2%, 1%, or 0.5% of the given value or range.

Ordinal numbers such as “first” and “second” used in the specification and the claims are used to modify elements, and the terms do not imply and represent that the element(s) have any previous ordinal numbers, nor do they represent the order of a certain element and another element or the order of a manufacturing method. The use of the ordinal numbers is only to clearly distinguish between an element with a certain name and another element with the same name. The claims and the specification may not use the same terms, whereby a first component in the specification may be a second component in the claims.

It should be noted that in the following embodiments, features in several different embodiments may be replaced, recombined, and mixed to complete other embodiments without departing from the spirit of the disclosure. As long as the features of the various embodiments do not violate the spirit of the invention or conflict with each other, the features may be arbitrarily mixed and matched for use.

Electrical connection or coupling described in the disclosure may refer to both direct connection or indirect connection. In the case of direct connection, terminals of elements on two circuits are directly connected or connected to each other by a conductor segment. In the case of indirect connection, there is a switch, a diode, a capacitor, an inductor, other suitable elements, or a combination of the above elements between the terminals of the elements on the two circuits, but not limited thereto.

In the disclosure, the measurement manner of thickness, length, width, and area may be by adopting an optical microscope, and the thickness may be obtained by measuring a cross-sectional image in an electron microscope, but not limited thereto. In addition, there may be a certain error in any two values or directions for comparison. If a first value is equal to a second value, it implies that there may be an error of about 10% between the first value and the second value. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

A manufacturing process of an electronic device of the disclosure may be provided, for example, through a wafer-level package (WLP) process or a panel-level package (PLP) process, which may be a chip first process or a chip last process.

The electronic device of the disclosure may be applied to a power module, a semiconductor package device, a display device, a light emitting device, a backlight device, an antenna device, a sensing device, or a splicing device, but not limited thereto. The electronic device includes a rollable, bendable, or flexible electronic device, but not limited thereto. The display device may be a non-self-luminous display device or a self-luminous display device. The electronic device may, for example, include a diode, liquid crystal, a light emitting diode (LED), quantum dot (QD), fluorescence, phosphor, other suitable display media, or a combination thereof. The antenna device may be a liquid crystal antenna device or a non-liquid crystal antenna device, and the sensing device may be a sensing device for sensing capacitance, light, heat energy, or ultrasonic waves, but not limited thereto. The light emitting diodes may include, for example, an organic light emitting diode (OLED), a micro LED, a mini LED, or a quantum dot LED (QLED or QDLED), but not limited thereto. The splicing device may, for example, be a display splicing device or an antenna splicing device, but not limited thereto. It should be noted that the electronic device may be any permutation and combination of the above, but not limited thereto. In addition, the appearance of the electronic device may be a rectangle, a circle, a polygon, a shape with curved edges, or other suitable shapes. The electronic device may have a peripheral system such as a driving system, a control system, and a light source system to support the display device, the antenna device, a wearable device (such as including augmented reality or virtual reality), a vehicle-mounted device (such as including a car windshield), or the splicing device. The electronic device may include an electronic element, wherein the electronic element may include passive elements and active elements, such as a capacitor, a resistor, an inductor, a diode, a transistor, and a sensor. It should be noted that the electronic device of the disclosure may be various combinations of the above devices, but not limited thereto. A manufacturing method of a package device of the disclosure may be, for example, applied to the wafer-level package (WLP) process or the panel-level package (PLP) process, wherein the wafer-level package or panel-level package process may include the chip first process or the chip last process, but not limited thereto. The electronic device may include a package device such as high bandwidth memory (HBM) package, system on chip (SoC), system in package (SiP), antenna in package (AiP), co-packaged optics (CPO), or various combinations of the above devices, but not limited thereto.

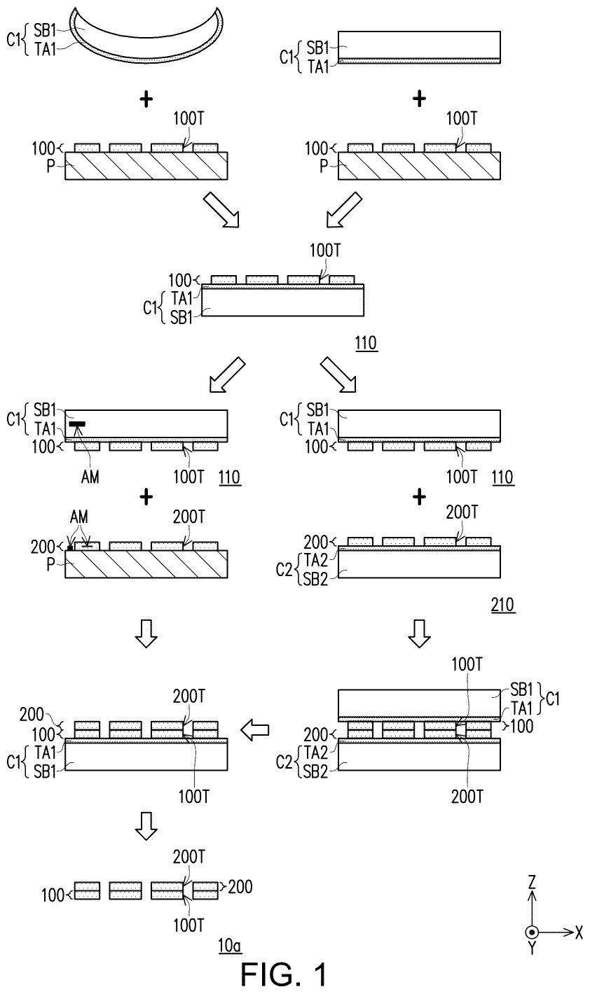

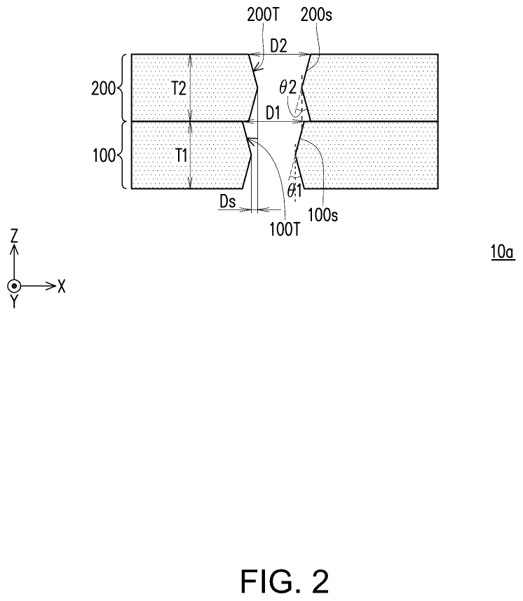

FIG. 1 is a flow schematic diagram of a manufacturing method of a perforation substrate according to an embodiment of the disclosure, and FIG. 2 is a cross-sectional schematic diagram of a perforation substrate according to a first embodiment of the disclosure.

Please refer to FIG. 1. In the embodiment, a perforation substrate 10a may be formed through performing the following steps, but the disclosure is not limited thereto.

Step (1) is performed to provide a carrier C1.

In some embodiments, the carrier C1 has a panel-level size (that is, the area of the carrier C1 is, for example, 30 cm×30 cm, 50 cm×50 cm, 70 cm×70 cm, or other square panel-level sizes, but not limited thereto). Based on this, a subsequent process to be performed in the embodiment may be an application of a fan-out panel-level package (FOPLP) process, wherein the fan-out panel-level package includes the wafer-first process or the wafer-last process. In the embodiment, the fan-out panel-level package process may significantly improve production capacity compared to the wafer-level package process because the carrier C1 with the panel-level size is adopted. At the same time, the carrier C1 with the panel-level size has a rectangular contour, which may also greatly increase the utilization of the carrier C1 compared to the wafer-level package process. Therefore, an electronic device 10 manufactured through the embodiment may be used to implement the requirement of high production capacity.

In the embodiment, the carrier C1 has a base layer SB1 and a temporary adhesive layer TA1.

The base layer SB1 may, for example, be a glass substrate, a silicon substrate, a sapphire substrate, or other suitable substrates and may have sufficient rigidity to withstand subsequent processes to be performed.

The temporary adhesive layer TA1 is, for example, disposed on the base layer SB1. The provision of the temporary adhesive layer TA1 enables components subsequently disposed on the carrier C1 to be relatively easily separated therefrom. In some embodiments, the material of the temporary adhesive layer TA1 may be selected as a suitable organic material, but the disclosure is not limited thereto.

Step (2) is performed to provide a first sub-perforation substrate 100 disposed on a platform P.

In some embodiments, the platform P may include a moving unit (not shown), a lifting unit (not shown), and/or a rotating unit (not shown), but the disclosure is not limited thereto. The moving unit may be used to horizontally move the platform P on a plane formed by a direction X and a direction Y, the lifting unit may be used to vertically move the platform P in a direction Z, and the rotating unit may be used to rotate the platform P around the direction X, the direction Y, and/or the direction Z.

The material of the first sub-perforation substrate 100 may include a suitable ceramic material. For example, the material of the first sub-perforation substrate 100 includes a transparent material, glass, alkali-free glass, and quartz glass, but the disclosure is not limited thereto. The coefficient of thermal expansion of the first sub-perforation substrate 100 may be greater than or equal to 3 ppm/°C. and less than or equal to 10 ppm/°C. The light transmittance of the first sub-perforation substrate 100 may be greater than or equal to 75%, wherein light may include white light, UV light, etc. In the embodiment, the first sub-perforation substrate 100 includes a plurality of perforations 100T, which may be formed through performing a laser process, a drilling process, an etching process, or a combination thereof, but the disclosure is not limited thereto. So as to say, the perforation seems like a through hole penetrating the substrate.

Step (3) is performed to perform a first laminating step to laminate the base layer SB1 to the first sub-perforation substrate 100 through the temporary adhesive layer TA1 to form a substrate structure 110. In the embodiment, the thickness of the substrate structure 110 is greater than or equal to 0.5 mm. In addition, in some embodiments, the thickness of the base layer SB1 is different from the thickness of the first sub-perforation substrate 100, and the rigidity of the base layer SB1 is different from the rigidity of the first sub-perforation substrate 100. In detail, the thickness of the base layer SB1 may be greater than the thickness of the first sub-perforation substrate 100, and the rigidity of the base layer SB1 may be greater than the rigidity of the first sub-perforation substrate 100.

In some embodiments, the first laminating step includes moving the carrier C1 from a first position to a second position, so that the base layer SB1 of the carrier C1 is in contact with the first sub-perforation substrate 100. Specifically, in the embodiment, the carrier C1 moves from the first position to the second position along a normal direction (the direction Z) of the platform P, and a distance between the first position and the platform P is greater than a distance between the second position and the platform P.

In some other embodiments, before performing the first laminating step, the carrier C1 may be bent, as shown in FIG. 1, but the disclosure is not limited thereto. Through the above manner, the quality of lamination may be improved and residual bubbles may be reduced, but not limited thereto.

It is worth noting that after laminating the base layer SB1 to the first sub-perforation substrate 100, the first sub-perforation substrate 100 is separated from the platform P.

Step (4) is performed to provide a second sub-perforation substrate 200, and the second sub-perforation substrate 200 is laminated to the first sub-perforation substrate 100.

The material of the second sub-perforation substrate 200 may be the same as or similar to the material of the first sub-perforation substrate 100, and a method for forming the second sub-perforation substrate 200 may be the same as or similar to the method for forming the first sub-perforation substrate 100, which will not be described in detail herein.

In some embodiments, the second sub-perforation substrate 200 may be laminated to the first sub-perforation substrate 100 through performing a second laminating step below, but the disclosure is not limited thereto.

First, the second sub-perforation substrate 200 disposed on the platform P is provided.

Thereafter, the substrate structure 110 is moved from a third position to a fourth position, so that the first sub-perforation substrate 100 of the substrate structure 110 is in contact with the second sub-perforation substrate 200. In detail, in the embodiment, the substrate structure 110 moves from the third position to the fourth position along the normal direction (direction Z) of the platform P, and a distance between the third position and the platform P is greater than a distance between the fourth position and the platform P.

Then, a heat treatment process is performed on the first sub-perforation substrate 100 and the second sub-perforation substrate 200 in contact with each other. In the embodiment, the temperature required for performing the second laminating step is higher than the temperature required for performing the first laminating step. In some embodiments, the temperature of performing the heat treatment process is at least greater than the glass transition temperature of the first sub-perforation substrate 100 and/or the glass transition temperature of the second sub-perforation substrate 200. Therefore, after performing the heat treatment process, the first sub-perforation substrate 100 and/or the second sub-perforation substrate 200 may be transformed from a glass state to a rubber state with adhesiveness, so that the first sub-perforation substrate 100 and the second sub-perforation substrate 200 may be laminated to each other. In addition, the first sub-perforation substrate 100 and the second sub-perforation substrate 200 may also be laminated to each other due to the Van der Waals force generated by the surfaces in contact with each other. Based on this, in the embodiment, no additional adhesive layer needs to be formed to laminate the second sub-perforation substrate 200 to the first sub-perforation substrate 100. It is worth noting that in the embodiment, before performing the second laminating step, the second sub-perforation substrate 200 and the first sub-perforation substrate 100 may be first aligned through an alignment marker AM to reduce a misalignment (for example, a misalignment Ds in FIG. 2) between the second sub-perforation substrate 200 and the first sub-perforation substrate 100 in the direction X.

Then, the carrier C1 may be selectively removed, but the disclosure is not limited thereto.

It is worth noting that after laminating the first sub-perforation substrate 100 to the second sub-perforation substrate 200 of the substrate structure 110, the second sub-perforation substrate 200 is separated from the platform P.

In some other embodiments, the second sub-perforation substrate 200 may be laminated to the first sub-perforation substrate 100 through performing the second laminating step below, but the disclosure is not limited thereto.

First, the second sub-perforation substrate 200 is laminated to a carrier C2 to form a substrate structure 210. In detail, the carrier C2 has a base layer SB2 and a temporary adhesive layer TA2, so that the base layer SB2 is laminated to the second sub-perforation substrate 200 through the temporary adhesive layer TA2. The material of the carrier C2 may be the same as or similar to the material of the carrier C1, which will not be described in detail herein.

Then, the first sub-perforation substrate 100 is laminated to the second sub-perforation substrate 200, which may be referred to the above embodiment and will not be described in detail herein.

Next, the carrier C2 is removed to form a perforation substrate 10a. The carrier C2 may be removed through performing a suitable stripping process, but the disclosure is not limited thereto. It is worth noting that the carrier C2 may be selectively removed, but the disclosure is not limited thereto.

In the embodiment, the first laminating step is performed to laminate the base layer SB1 to the first sub-perforation substrate 100 through the temporary adhesive layer to form the substrate structure 110, which has a relatively large rigidity due to the increased thickness. Afterwards, the substrate structure 110 is laminated to the second sub-perforation substrate 200 to form the perforation substrate 10a with a high aspect ratio, and the possibility of damage during the perforation process and/or the laminating process due to insufficient rigidity of a single sub-perforation substrate may be reduced.

Please refer to FIG. 2. The perforation substrate 10a includes the first sub-perforation substrate 100 and the second sub-perforation substrate 200, wherein the first sub-perforation substrate 100 includes the first perforations 100T, and the second sub-perforation substrate 200 includes multiple second perforations 200T. In the embodiment, the first perforations 100T at least partially overlap with the corresponding second perforations 200T in the normal direction (direction Z) of the first sub-perforation substrate 100.

In the embodiment, the perforation substrate 10a has the following characteristics, but the disclosure is not limited thereto.
(A) The misalignment Ds between the second sub-perforation substrate 200 and the first sub-perforation substrate 100 in the direction X is less than or equal to 5 μm. In detail, the misalignment Ds between the second sub-perforation substrate 200 and the first sub-perforation substrate 100 in the direction X is greater than or equal to 0.1 μm and less than or equal to 5 μm. Through the above limitation, the electrical characteristics may be improved, but not limited thereto.
(B) A thickness T1 of the perforation 100T of the first sub-perforation substrate 100 in the direction Z is less than or equal to 0.3 mm, and a thickness T2 of the perforation 200T of the second sub-perforation substrate 200 in the direction Z is less than or equal to 0.3 mm.
(C) A maximum width D1 of the perforation 100T of the first sub-perforation substrate 100 in the direction X is less than or equal to 100 μm, and a maximum width D2 of the perforation 200T of the second sub-perforation substrate 200 in the direction X is less than or equal to 100 μm.
(D) An angle θ1 between a side 100s of the first sub-perforation substrate 100 and the direction Z is less than or equal to 10 degrees, an angle θ2 between a side 200s of the second sub-perforation substrate 200 and the direction Z is less than or equal to 10 degrees, and a difference value between the angle θ1 and the angle θ2 should be less than or equal to 5 degrees to reduce the defective rate of subsequent processes. For example, when the angle difference value is too large, the continuity of a subsequently deposited thin film may be affected, but not limited thereto.

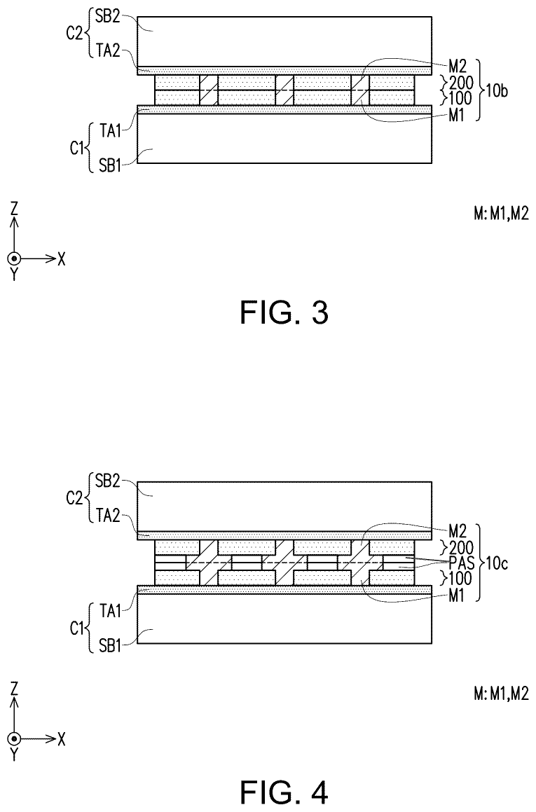

FIG. 3 is a cross-sectional schematic diagram of a perforation substrate according to a second embodiment of the disclosure. It should be noted that the embodiment of FIG. 3 may continue to use the reference numerals and some content of the embodiment of FIG. 1, wherein the same or similar numerals are adopted to represent the same or similar elements, and the description of the same technical content is omitted.

The difference between a perforation substrate 10b of FIG. 3 and the perforation substrate 10a is that the perforation substrate 10b further includes a conductive layer M.

In detail, a conductive layer M1 may be formed in the perforation 100T of the first sub-perforation substrate 100, and a conductive layer M2 may be formed in the perforation 200T of the second sub-perforation substrate 200, and the conductive layer M1 and the conductive layer M2 are in contact with each other and electrically connected.

In some embodiments, the conductive layer M1 and the conductive layer M2 may be formed through performing the following steps, but the disclosure is not limited thereto.

Taking the formation of the conductive layer M1 as an example, first, a seed layer (not shown) is formed on one side of the first sub-perforation substrate 100. Then, an electroplating process is performed to grow the seed layer to form the conductive layer M1. Similarly, the conductive layer M2 may also be formed through this method.

The conductive layer M1 and the conductive layer M2 may be formed before laminating the first sub-perforation substrate 100 to the second sub-perforation substrate 200, thereby reducing the possibility that the conductive layer M1 and/or the conductive layer M2 are not completely formed in the corresponding perforations.

FIG. 4 is a cross-sectional schematic diagram of a perforation substrate according to a third embodiment of the disclosure. It should be noted that the embodiment of FIG. 4 may continue to use the reference numerals and some content of the embodiment of FIG. 3, wherein the same or similar numerals are adopted to represent the same or similar elements, and the description of the same technical content is omitted.

The difference between a perforation substrate 10c of FIG. 4 and the perforation substrate 10b is that the perforation substrate 10c further includes an insulating layer PAS.

In detail, the insulating layer PAS may be formed between the first sub-perforation substrate 100 and the second sub-perforation substrate 200, and the insulating layer PAS does not overlap with the perforation 100T and the perforation 200T in the direction Z.

In some embodiments, the insulating layer PAS may be formed between the first sub-perforation substrate 100 and the second sub-perforation substrate 200 through performing a suitable deposition process, but the disclosure is not limited thereto.

Since the conductive layer M1 and/or the conductive layer M2 may protrude from the corresponding perforation, a gap may be generated after the first sub-perforation substrate 100 is laminated to the second sub-perforation substrate 200. In the embodiment, through disposing the insulating layer PAS, the conductive layer M1 and/or the conductive layer M2 may be flush with the insulating layer PAS on the plane formed by the direction X and the direction Y, in detail, the conductive layer M1 and/or the conductive layer M2 may be coplanar with the insulating layer PAS by the direction X and the direction Y, so as to reduce the possibility of such a technical issue being generated. In other words, the surface roughness of the insulating layer PAS may be less than the surface roughness of the conductive layer M1 and/or the conductive layer M2. The thickness of the insulating layer PAS may be less than or equal to 3 μm. The material of the insulating layer PAS may include oxide, nitride, or other suitable insulating materials.

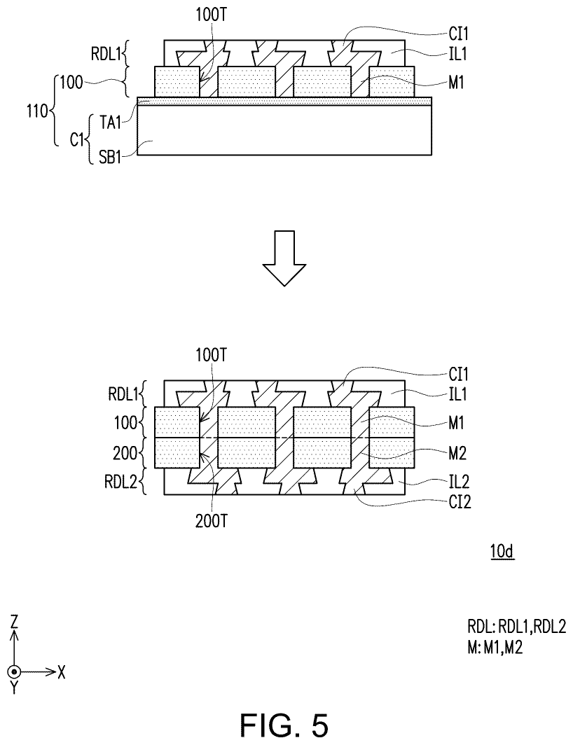

FIG. 5 is a flow schematic diagram of a manufacturing method of a perforation substrate according to a fourth embodiment of the disclosure. It should be noted that the embodiment of FIG. 5 may continue to use the reference numerals and some content of the embodiments of FIG. 1 and FIG. 3, wherein the same or similar numerals are adopted to represent the same or similar elements, and the description of the same technical content is omitted.

The main difference between a method for forming a perforation substrate 10d of FIG. 5 and the method for forming the perforation substrate 10a is that the second sub-perforation substrate 200 is laminated to the first sub-perforation substrate 100 to form a redistribution structure RDL. The redistribution structure RDL is defined to include at least one conductive layer and at least one insulating layer, and is used to redistribute circuits and/or further increase a circuit fan-out area. In addition, different electronic elements may be electrically connected to each other through the redistribution structure RDL. For example, electronic elements E1 may be electrically connected to each other through the redistribution structure RDL or the redistribution structure RDL may be a substrate for distributing an electrical interface between one connection and another connection. The manner for forming the redistribution structure RDL includes, for example, providing a stack of the at least one insulating layer and the at least one conductive layer, and the manufacturing process thereof includes a manufacturing process such as lithography, etching, surface treatment, laser, and electroplating. The surface treatment includes roughening the surface of the insulating layer or the conductive layer to improve the adhesion ability. The purpose of RDL is to expand a cable to a wider spacing or redistribute a cable to another cable with a different spacing. A dielectric layer of the redistribution structure RDL may be polyimide (PI), polyphenylene sulfide (PPS), polybenzoxazole (PBO), epoxy, polymer, isoaniline, silicon oxide (SiOx), or silicon nitride (SiNx).

In the embodiment, after forming the substrate structure 110, the conductive layer M1 is formed in the perforation 100T of the first sub-perforation substrate 100. A method for forming the conductive layer M1 may refer to the embodiment shown in FIG. 3, which will not be described in detail herein. Similarly, after forming the substrate structure 210, the conductive layer M2 is formed in the perforation 200T of the second sub-perforation substrate 200.

Next, an insulating layer IL1 is formed on the conductive layer M1, wherein the insulating layer IL1 has an opening exposing a part of the conductive layer M1. The insulating layer IL1 may be formed through a suitable deposition process and patterning process, but the disclosure is not limited thereto. Similarly, an insulating layer IL2 is formed on the conductive layer M2, wherein the insulating layer IL2 has an opening exposing a part of the conductive layer M2. In some embodiments, the thickness of the insulating layer IL1 is 5 μm to 15 μm, but the disclosure is not limited thereto.

Afterwards, a circuit layer CI1 is formed in the opening of the insulating layer IL1 to be electrically connected to the conductive layer M1 to form a redistribution structure RDL1. Similarly, a circuit layer CI2 is formed in the opening of the insulating layer IL2 to be electrically connected to the conductive layer M2 to form a redistribution structure RDL2.

Then, the carrier C1 and the carrier C2 are removed, and the second sub-perforation substrate 200 is laminated to the first sub-perforation substrate 100, wherein the redistribution structure RDL1 is electrically connected to the redistribution structure RDL2.

In the embodiment, through first forming the redistribution structure RDL before laminating the second sub-perforation substrate 200 to the first sub-perforation substrate 100, the possibility of warpage of the perforation substrate 10d may be reduced.

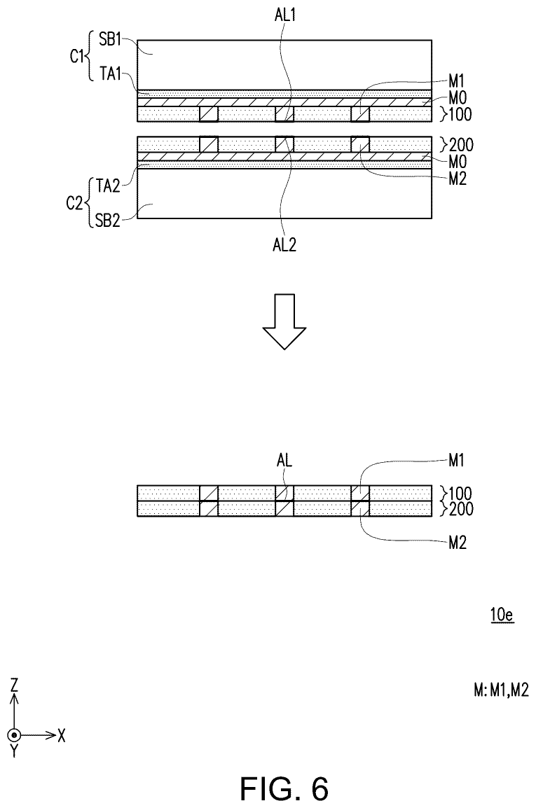

FIG. 6 is a flow schematic diagram of a manufacturing method of a perforation substrate according to a fifth embodiment of the disclosure. It should be noted that the embodiment of FIG. 6 may continue to use the reference numerals and some content of the embodiment of FIG. 3, wherein the same or similar numerals are adopted to represent the same or similar elements, and the description of the same technical content is omitted.

The difference between a perforation substrate 10e of FIG. 6 and the perforation substrate 10c is that the perforation substrate 10e further includes a conductive layer M0 and an auxiliary layer AL.

In the embodiment, before laminating the base layer SB1 to the first sub-perforation substrate 100 through the temporary adhesive layer TA1, the conductive layer M0 is formed on a surface of the temporary adhesive layer TA1 away from the base layer SB1. Similarly, before laminating the base layer SB2 to the second sub-perforation substrate 200 through the temporary adhesive layer TA2, the conductive layer M0 is formed on a surface of the temporary adhesive layer TA2 away from the base layer SB2. A method for forming the conductive layer M0 may be through performing a physical vapor deposition process or a chemical vapor deposition process, but the disclosure is not limited thereto. In the embodiment, the conductive layer M0 serves as a seed layer for growing the conductive layer M1 and/or the conductive layer M2, but the disclosure is not limited thereto.

The auxiliary layer AL includes an auxiliary layer AL1 and an auxiliary layer AL2, wherein the auxiliary layer AL1 is formed on a surface of the conductive layer M1 away from the base layer SB1, and the auxiliary layer AL2 is formed on a surface of the conductive layer M2 away from the base layer SB2. After laminating the second sub-perforation substrate 200 to the first sub-perforation substrate 100, the auxiliary layer AL1 and the auxiliary layer AL2 may contact each other. The auxiliary layer AL1 may be, for example, used to lower the process temperature for laminating the second sub-perforation substrate 200 to the first sub-perforation substrate 100, that is, the second sub-perforation substrate 200 may be laminated to the first sub-perforation substrate 100 at a lower process temperature, but the disclosure is not limited thereto. In some embodiments, the material of the auxiliary layer AL may include gold (Au), palladium (Pd), silver (Ag), platinum (Pt), ruthenium (Ru), gallium (Ga), or other suitable materials, but the disclosure is not limited thereto. In some embodiments, the thickness of the auxiliary layer AL1 and the thickness of the auxiliary layer AL2 may be respectively greater than or equal to 0.01 μm and less than or equal to 1 μm, but the disclosure is not limited thereto.

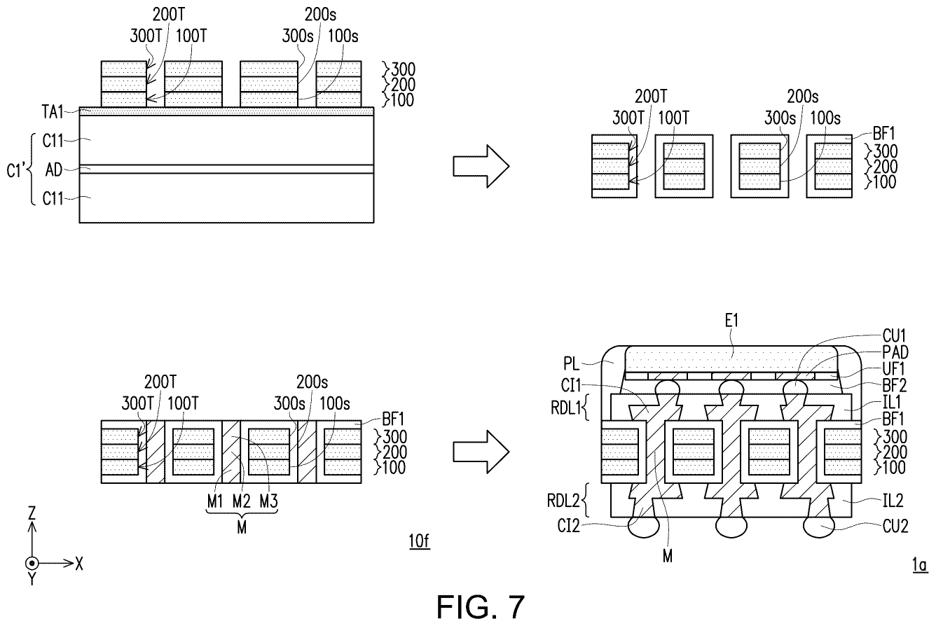

FIG. 7 is a flow schematic diagram of a manufacturing method of an electronic device according to the first embodiment of the disclosure. It should be noted that the embodiment of FIG. 7 may continue to use the reference numerals and some content of the embodiments of FIG. 1, FIG. 3, and FIG. 5, wherein the same or similar numerals are adopted to represent the same or similar elements, and the description of the same technical content is omitted.

Please refer to FIG. 7. In the embodiment, a carrier C1′ includes multi-stacked glass structure like a glass substrate on glass substrate (called GOG) structure, that is, the carrier C1′ may include more than two layers of a glass substrate stacked along the direction Z. For example, the carrier C1′ may include two sub-carriers C11 and an adhesive layer AD, and the two sub-carriers C11 are bonded to each other through the adhesive layer AD, but the disclosure is not limited thereto. In addition, in the embodiment, a third sub-perforation substrate 300 is laminated to the second sub-perforation substrate 200. The laminating method may be the same as or similar to the method for laminating the second sub-perforation substrate 200 to the first sub-perforation substrate 100, which will not be described in detail herein.

Next, step (5) is performed to form a buffer layer BF1 in the perforation 100T of the first sub-perforation substrate 100, the perforation 200T of the second sub-perforation substrate 100, and a perforation 300T of the third sub-perforation substrate 300.

The buffer layer BF1 may be, for example, formed through a suitable deposition process, but the disclosure is not limited thereto. Through disposing the buffer layer BF1, the buffer layer BF1 may cover the side 100s of the first sub-perforation substrate 100, the side 200s of the second sub-perforation substrate 200, and a side 300s of the third sub-perforation substrate 300, and may fill pits generated on the corresponding sides after the perforation 100T, the perforation 200T, and/or the perforation 300T are formed, so as to reduce the possibility of defects in subsequently formed conductive layer M1, conductive layer M2, and/or conductive layer M3. In some embodiments, the material of the buffer layer BF1 may include a suitable organic material and/or inorganic material. For example, the material of the buffer layer BF1 may include polyimide (PI), parylene, benzocyclobutene (BCB), epoxy, polycarbonate (PC), polyethylene terephthalate (PET), polyethylene naphthalate (PEN), or a combination thereof, but the disclosure is not limited thereto. In some embodiments, the buffer layer BF1 may include a multi-layer structure. For example, the buffer layer BF1 may include a stacked structure of inorganic layer/organic layer/inorganic layer, but the disclosure is not limited thereto. In some embodiments, the buffer layer BF1 may have a toughness of 0.1 kJ/m² to 100 kJ/m², but the disclosure is not limited thereto.

In other words, after the perforation 100T, the perforation 200T, and the perforation 300T are formed, the side 100s of the first sub-perforation substrate 100, the side 200s of the second sub-perforation substrate 200, and the side 300s of the third sub-perforation substrate 300 may respectively have a relatively large roughness. Through forming the buffer layer BF1, the roughness of each of the side 100s of the first sub-perforation substrate 100, the side 200s of the second sub-perforation substrate 200, and the side 300s of the third sub-perforation substrate 300 may be relatively reduced. In some embodiments, the roughness determination is defined as observing the side of each sub-perforation substrate using a scanning electron microscope (SEM) or a transmission electron microscope (TEM), wherein if a difference between undulating peaks and valleys of a side surface is 0.15 μm to 1 μm, the roughness may be regarded as low. The scanning electron microscope or the transmission electron microscope may be used to observe undulations of the side surface of each sub-perforation substrate at the same appropriate magnification, and the undulations may be compared by taking a unit length (for example, 10 μm), wherein “appropriate magnification” means that at least 10 undulating peaks may be seen on at least one surface under the field of view of this magnification.

In some embodiments, the thickness of the buffer layer BF1 may be less than the thickness of the insulating layer IL1. The thickness of the buffer layer BF1 may, for example, be 0.01 μm to 10 μm, but the disclosure is not limited thereto.

Thereafter, step (6) is performed to form the conductive layer M in the perforation 100T of the first sub-perforation substrate 100, the perforation 200T of the second sub-perforation substrate 100, and the perforation 300T of the third sub-perforation substrate 300.

In detail, the conductive layer M1 may be formed in the perforation 100T of the first sub-perforation substrate 100, the conductive layer M2 may be formed in the perforation 200T of the second sub-perforation substrate 200, the conductive layer M3 may be formed in the perforation 300T of the third sub-perforation substrate 300, and the conductive layer M1, the conductive layer M2, and the conductive layer M3 are in contact with each other and electrically connected. A method for forming the conductive layer M may refer to the embodiment shown in FIG. 3, which will not be described in detail herein.

From another perspective, the buffer layer BF1 is disposed between the conductive layer M1 and the first sub-perforation substrate 100, disposed between the conductive layer M2 and the second sub-perforation substrate 200, and disposed between the conductive layer M3 and the third sub-perforation substrate 300. Through disposing the buffer layer BF1, the possibility of incomplete filling of the corresponding perforations in the conductive layer M1, the conductive layer M2, and/or the conductive layer M3 may be reduced.

Then, step (7) is performed to form the redistribution structure RDL to form a perforation substrate 10f.

A method for forming the redistribution structure RDL may refer to the embodiment shown in FIG. 5, which will not be described in detail herein.

Thereafter, step (8) is performed to bond the electronic element E1 to the perforation substrate 10f to form an electronic device 1a, wherein the electronic element E1 is electrically connected to the redistribution structure RDL1.

In the embodiment, the electronic element E1 may be electrically connected to the redistribution structure RDL1 through a pad PAD of the electronic element E1 and a connection element CU1, wherein the connection element CU1 is disposed between the pad PAD and the redistribution structure RDL1. The material of the connection element CU1 may include copper, nickel (Ni), tin (Sn), silver, gold, gallium, or other suitable materials, but the disclosure is not limited thereto. The electronic element E1 may, for example, be a conventional integrated circuit (IC), an active element, or a passive element, but the disclosure is not limited thereto.

In the embodiment, the electronic device 1a further includes a buffer layer BF2. The buffer layer BF2 is, for example, disposed between the electronic element E1 and the redistribution structure RDL1. In detail, the buffer layer BF2 may cover the connection element CU1 and be in contact with the pad PAD of the electronic element E1 to protect the connection element CU1 and the pad PAD, which may reduce the possibility of the electronic element E1 and the redistribution structure RDL1 not being bonded. The material of the buffer layer BF2 may include a suitable inorganic material or organic material, but the disclosure is not limited thereto.

In the embodiment, the electronic device 1a further includes a glue layer UF1. The glue layer UF1 is, for example, disposed between the electronic element E1 and the buffer layer BF2. In detail, the glue layer UF1 may be directly in contact with an active surface of the electronic element E1 and fill a space between two adjacent connection elements CU1. The material of the glue layer UF1 may include a suitable inorganic material or organic material, but the disclosure is not limited thereto.

In the embodiment, the electronic device 1a further includes an encapsulation layer PL. The encapsulation layer PL surrounds, for example, the electronic element E1. In some other embodiments, the encapsulation layer PL may cover the electronic element E1, but the disclosure is not limited thereto. The material of the encapsulation layer PL may include an epoxy molding compound (EMC), but the disclosure is not limited thereto.

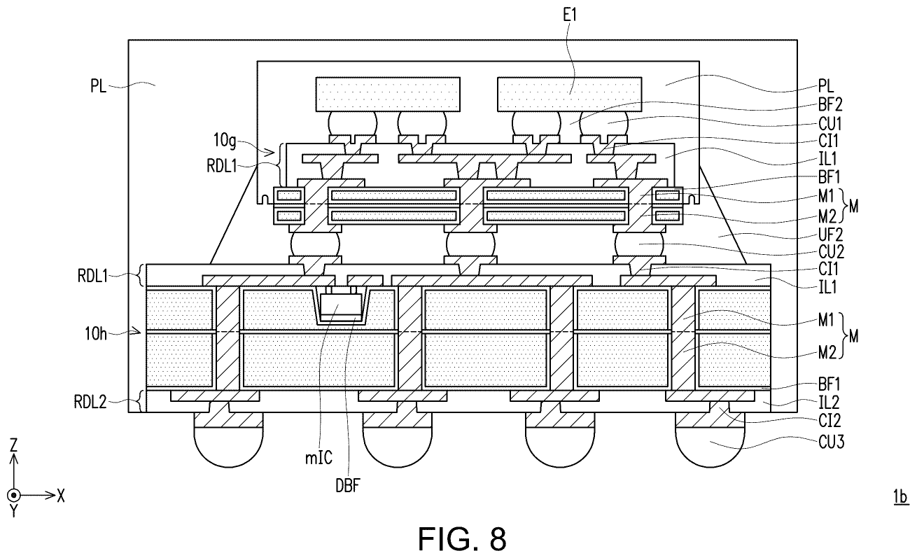

FIG. 8 is a partial cross-sectional schematic diagram of an electronic device according to the second embodiment of the disclosure. It should be noted that the embodiment of FIG. 8 may continue to use the reference numerals and some content of the embodiment of FIG. 7, wherein the same or similar numerals are adopted to represent the same or similar elements, and the description of the same technical content is omitted.

Please refer to FIG. 8. In the embodiment, an electronic device 1b includes the electronic element E1, a perforation substrate 10g, and a perforation substrate 10h, wherein the perforation substrate 10g and the perforation substrate 10h are bonded to each other through a connection element CU2 and a glue layer UF2. Components included in the perforation substrate 10g and the perforation substrate 10h may refer to the above embodiments, which will not be described in detail herein.

In the embodiment, the perforation substrate 10h further includes a micro integrated circuit mIC. The micro integrated circuit mIC is, for example, disposed in a groove of the first sub-perforation substrate 100 and may be laminated to the first sub-perforation substrate 100 through a chip adhesive film DBF. In other words, an active surface of the micro integrated circuit mIC may, for example, face the perforation substrate 10g.

In the embodiment, the perforation substrate 10h further includes a connection element CU3. The connection element CU3 is disposed on a surface of the second sub-perforation substrate 200 away from the first sub-perforation substrate 100 and may be, for example, used to be bonded to another perforation substrate or other interposers, but the disclosure is not limited thereto.

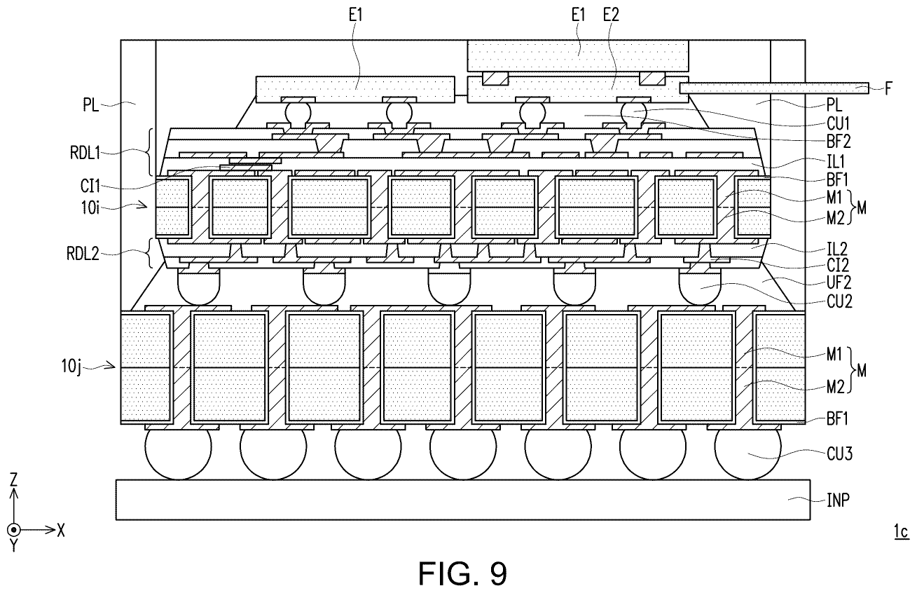

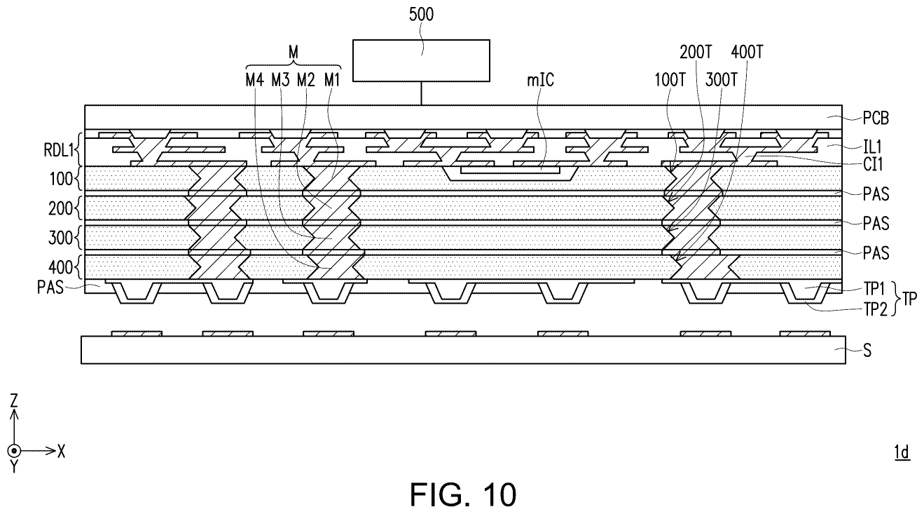

FIG. 9 is a partial cross-sectional schematic diagram of an electronic device according to the third embodiment of the disclosure. It should be noted that the embodiment of FIG. 9 may continue to use the reference numerals and some content of the embodiment of FIG. 8, wherein the same or similar numerals are adopted to represent the same or similar elements, and the description of the same technical content is omitted.

Please refer to FIG. 9. In the embodiment, an electronic device 1c includes the electronic element E1, an electronic element E2, a perforation substrate 10i, and a perforation substrate 10j, wherein the perforation substrate 10i and the perforation substrate 10j are bonded to each other through the connection element CU2 and the glue layer UF2. Components included in the perforation substrate 10i and the perforation substrate 10j may refer to the above embodiments, which will not be described in detail herein.

In the embodiment, the electronic element E2 is a photonic integrated circuit (PIC). In detail, the electronic element E2 may establish a communication path through an optical fiber F, wherein a part of the optical fiber F is embedded in the encapsulation layer PL, but the disclosure is not limited thereto.

In the embodiment, the electronic device 1c is formed on an interposer INP. In some embodiments, the electronic device 1c may be a chip on wafer on substrate (CoWoS) package structure, but not limited thereto. That is, although only one electronic device 1c is shown in FIG. 9, the package structure of the embodiment may include multiple different or identical electronic devices, which may be disposed on the interposer INP at the same horizontal height to implement a 2.5D package structure of the electronic devices are placed horizontally side by side, but the disclosure is not limited thereto. In some embodiments, the interposer INP may be a silicon (Si) interposer, a glass interposer, or an organic interposer, but the disclosure is not limited thereto.

FIG. 10 is a partial cross-sectional schematic diagram of an electronic device according to the fourth embodiment of the disclosure. It should be noted that the embodiment of FIG. 10 may continue to use the reference numerals and some content of the embodiment of FIG. 8, wherein the same or similar numerals are adopted to represent the same or similar elements, and the description of the same technical content is omitted.

Please refer to FIG. 10. In the embodiment, an electronic device 1d is a testing device. In detail, the electronic device 1d may include a perforation substrate 10k and a probe needle TP.

The perforation substrate 10k is, for example, disposed on a circuit board PCB and electrically connected to the circuit board PCB. In some embodiments, the perforation substrate 10k may be electrically connected to a control unit 500 through the circuit board PCB, but the disclosure is not limited thereto.

In the embodiment, the perforation substrate 10k includes the first sub-perforation substrate 100, the second sub-perforation substrate 200, the third sub-perforation substrate 300, and a fourth sub-perforation substrate 400. The conductive layer M1 may be formed in the perforation 100T of the first sub-perforation substrate 100, the conductive layer M2 may be formed in the perforation 200T of the second sub-perforation substrate 200, the conductive layer M3 may be formed in the perforation 300T of the third sub-perforation substrate 300, a conductive layer M4 may be formed in a perforation 400T of the fourth sub-perforation substrate 400, and the conductive layer M1, the conductive layer M2, the conductive layer M3, and the conductive layer M4 are in contact with each other and electrically connected. The method for forming the conductive layer M may refer to the embodiment shown in FIG. 3, which will not be described in detail herein.

In the embodiment, the perforation substrate 10k further includes the micro integrated circuit mIC. The micro integrated circuit mIC is, for example, disposed in the groove of the first sub-perforation substrate 100 and may be electrically connected to the redistribution structure RDL1.

The probe needle TP may be in contact with the conductive layer M4 and be electrically connected to the perforation substrate 10k. In the embodiment, the probe needle TP may be used to perform electrical detection on a test sample S. For example, the probe needle TP may be in contact with the test sample S to perform an open circuit test or a short circuit test. In the embodiment, the probe needle TP may include a protruding portion TP1 and a protective layer TP2. The protruding portion TP1 and the protective layer TP2 may include suitable conductive layers, wherein the protective layer TP2 may protect the protruding portion TP1 from being oxidized by an external environment.

In summary, in the manufacturing method of the electronic device provided by some embodiments of the disclosure, through performing the first laminating step, the base layer is laminated to the first sub-perforation substrate through the temporary adhesive layer to form the substrate structure, which has the relatively large rigidity due to the increased thickness (thickness of greater than or equal to 0.5 mm). Afterwards, the substrate structure is used to perform the laminating process with the second sub-perforation substrate to form the perforation substrate with the high aspect ratio, and the possibility of damage during the perforation process and/or the laminating process due to insufficient rigidity of a single sub-perforation substrate may be reduced. Based on this, the electronic device including the perforation substrate provided by some embodiments of the disclosure may have an improved yield.

What is claimed is:

1. A manufacturing method of an electronic device, comprising:
providing a carrier, wherein the carrier has a base layer and a temporary adhesive layer disposed on the base layer;
providing a first sub-perforation substrate disposed on a platform;
performing a first laminating step to laminate the first sub-perforation substrate to the base layer through the temporary adhesive layer to form a substrate structure; and
providing a second sub-perforation substrate, and laminating the second sub-perforation substrate to the first sub-perforation substrate,
wherein when performing the first laminating step, along a normal direction of the platform, the carrier moves from a first position to a second position, and a distance between the first position and the platform is greater than a distance between the second position and the platform.

2. The manufacturing method of the electronic device according to claim 1, wherein the step of laminating the second sub-perforation substrate to the first sub-perforation substrate comprises:
providing the second sub-perforation substrate disposed on the platform, and performing a second laminating step to laminate the first sub-perforation substrate and the second sub-perforation substrate, wherein a temperature required for performing the second laminating step is higher than a temperature required for performing the first laminating step.

3. The manufacturing method of the electronic device according to claim 1, wherein the step of laminating the second sub-perforation substrate to the first sub-perforation substrate comprises:
providing another carrier;
laminating the second sub-perforation substrate to the another carrier to form another substrate structure;
laminating the first sub-perforation substrate to the second sub-perforation substrate; and
removing the another carrier.

4. The manufacturing method of the electronic device according to claim 1, wherein in the step of laminating the second sub-perforation substrate to the first sub-perforation substrate, the second sub-perforation substrate and the first sub-perforation substrate are aligned through an alignment marker.

5. The manufacturing method of the electronic device according to claim 1, wherein after laminating the second sub-perforation substrate to the first sub-perforation substrate, a misalignment between the second sub-perforation substrate and the first sub-perforation substrate in a first direction is less than or equal to 5 μm.

6. The manufacturing method of the electronic device according to claim 1, wherein before performing the first laminating step, the carrier is bent.

7. The manufacturing method of the electronic device according to claim 1, wherein a thickness of the substrate structure is greater than or equal to 0.5 mm.

8. The manufacturing method of the electronic device according to claim 1, wherein a thickness of the base layer is different from a thickness of the first sub-perforation substrate.

9. The manufacturing method of the electronic device according to claim 1, wherein a rigidity of the base layer is different from a rigidity of the first sub-perforation substrate.

10. The manufacturing method of the electronic device according to claim 1, wherein the carrier comprises multi-stacked glass structure.

11. An electronic device, comprising:
a first sub-perforation substrate, comprising a plurality of first perforations; and
a second sub-perforation substrate, laminated to the first sub-perforation substrate and comprising a plurality of second perforations,
wherein the first perforations at least partially overlap with the corresponding second perforations in a normal direction of the first sub-perforation substrate,
wherein a misalignment between the second sub-perforation substrate and the first sub-perforation substrate in a first direction is less than or equal to 5 μm, and the first direction is perpendicular to the normal direction of the first sub-perforation substrate,
wherein a thickness of one of the first perforations and one of the second perforations in the normal direction of the first sub-perforation substrate is less than or equal to 0.3 mm,
wherein a maximum width of one of the first perforations and one of the second perforations in the first direction is less than or equal to 100 μm,
wherein an angle between a side of the first sub-perforation substrate and the normal direction of the first sub-perforation substrate is less than or equal to 10 degrees, and an angle between a side of the second sub-perforation substrate and the normal direction of the first sub-perforation substrate is less than or equal to 10 degrees.

12. The electronic device according to claim 11, wherein the misalignment between the second sub-perforation substrate and the first sub-perforation substrate in the first direction is greater than or equal to 0.1 μm and less than or equal to 5 μm.

13. The electronic device according to claim 11, further comprising a first conductive layer and a second conductive layer, wherein the first conductive layer is disposed in the first perforations, the second conductive layer is disposed in the second perforations, and the first conductive layer is electrically connected to the second conductive layer.

14. The electronic device according to claim 13, further comprising a buffer layer, wherein the buffer layer covers the side of the first sub-perforation substrate and the side of the second sub-perforation substrate, and the buffer layer is disposed between the first conductive layer and the first sub-perforation substrate and is disposed between the second conductive layer and the second sub-perforation substrate.

15. The electronic device according to claim 13, further comprising a first redistribution structure, wherein the first redistribution structure is disposed on the first sub-perforation substrate and is electrically connected to the first conductive layer.

16. The electronic device according to claim 13, further comprising a second redistribution structure, wherein the second redistribution structure is disposed on the second sub-perforation substrate and is electrically connected to the second conductive layer.

17. The electronic device according to claim 11, further comprising an insulating layer, wherein the insulating layer is disposed between the first sub-perforation substrate and the second sub-perforation substrate, and the first conductive layer and/or the second conductive layer are coplanar with the insulating layer.

18. The electronic device according to claim 11, further comprising:
a first auxiliary layer, disposed on the first conductive layer; and
a second auxiliary layer, disposed on the second conductive layer,
wherein the first auxiliary layer and the second auxiliary layer are in contact with each other,
wherein a material of the first auxiliary layer and a material of the second auxiliary layer respectively comprise gold (Au), palladium (Pd), silver (Ag), platinum (Pt), ruthenium (Ru), gallium (Ga) or a combination thereof,
wherein a thickness of the first auxiliary layer and a thickness of the second auxiliary layer are respectively greater than or equal to 0.01 μm and less than or equal to 1 μm.

19. The electronic device according to claim 11, further comprising:
an electronic element, disposed on the first sub-perforation substrate and electrically connected to the first conductive layer.

20. The electronic device according to claim 19, further comprising:
an encapsulation layer, disposed on the first sub-perforation substrate and surrounding the electronic element.
